(19) United States
(12) Patent Application Publication
(10) Pub. No.: US 2005/0152424 A1
(43) Pub. Date: Jul. 14, 2005

(54) Low voltage defect super high efficiency diode sources

(76) Inventors: Viktor Borisovitch Khalfin, Hightstown, NJ (US); Joseph H. Abeles, East Brunswick, NJ (US); Martin Kwakernaak, New Brunswick, NJ (US); Ralph Doud Whaley JR., Princeton Junction, NJ (US); Haiyan An, Plainsboro, NJ (US)

Correspondence Address: PLOVY & HOWARD, PC, P. O. BOX 226, FORT WASHINGTON, PA, 19034, US

(21) Appl. No.: 10/922,795

(22) Filed: Aug. 20, 2004

Related U.S. Application Data
(60) Provisional application No. 60/496,444, filed on Aug. 20, 2003.

(51) Int. Cl. H01S 5/00; H01S 3/03; B32B 5/18

(52) U.S. Cl. 372/64

(57) ABSTRACT

A high efficiency, low voltage defect laser, and a method of forming a high efficiency laser. The low voltage defect laser includes at least one p-clad layer, at least one n-clad layer, and at least one waveguide of at least a plurality of quantum wells. The at least one waveguide is sandwiched at least between the p-clad layer and the n-clad layer, and at least one permeable crystal layer may be embedded in the p-clad layer and immediately adjacent to the at least one waveguide. The method includes growing an AlGaAs layer atop a GaAs layer, etching of the AlGaAs into submicron structure, oxidizing the AlGaAs, SAG undoped growing of an SAG undoped GaAs atop the GaAs layer, and regrowing, with p⁺⁺ doped GaAs, of a planar-buried p++ GaAs.

### CROSS REFERENCE TO RELATED APPLICATIONS

This Application claims the benefit of priority to copending U.S. Provisional Patent Application Ser. No. 60/496,444, entitled “LOW VOLTAGE DEFECT SUPER HIGH EFFICIENCY DIODE SOURCES”, filed Aug. 20, 2003, the entire disclosure of which is hereby incorporated by reference as if being set forth herein in its entirety.

### BACKGROUND OF THE INVENTION

The basic diode laser has been known and understood for some time. Since that time, improvements to the epistructure underlying semiconductor lasers have largely concentrated on two performance metrics, reducing threshold currents and increasing power.

Efficiency is typically a primary factor in a laser performance, often being determinative of the maximum emitted power. Because of a limited ability to remove heat, and the small size of diode lasers, high operating power often depends on achieving high laser efficiency. Differential quantum efficiencies above 90% have been demonstrated at wavelengths near 980 nm. However, achieving the highest efficiency diode laser is not dependent upon achieving the highest power diode laser.

With regard to the physics of light-emitting Ill-V heterostructures, bandgap engineering, in conjunction with advances in crystal growth, have led to doping, thickness and composition recipes that minimize threshold and maximize power. However, a third metric, namely power conversion efficiency (PCE), has remained largely unaddressed.

Conventional approaches have typically encountered difficulty in exceeding a 60% PCE. Typically, a maximum of 60% PCE results, in part, because of ˜10% PCE being unatainable due to threshold current, ˜15% PCE being unatainable due to voltage defect, ˜5% PCE being unatainable due to series resistance, and ˜5% PCE being unatainable due to optical propagation loss. The remaining ˜5% being unattainable may be attributed, at least in part, to an inability to operate the lasers equally along the length of the bar, in part owing to variation in lasing wavelength. Thus, in this simple model, a 20% increase in PCE might be attainable were wavelengths stabilized along the bar, and were voltage defect substantially or partially eliminated.

### BRIEF SUMMARY OF THE INVENTION

A low voltage defect laser system, including: at least one p-clad layer; at least one n-clad layer; and, at least one waveguide comprising at least a plurality of quantum wells; wherein said at least one waveguide is sandwiched at least between said p-clad layer and said n-clad layer, and the plurality of quantum wells is offset toward said p-clad layer.

### BRIEF DESCRIPTION OF THE SEVERAL VIEWS OF THE DRAWINGS

For the present invention to be clearly understood and readily practiced, the present invention will be described in conjunction with the following figures, wherein like reference numerals represent like elements, and wherein:

FIG. 1 illustrates a diagrammatic cross-section of a device according to an aspect of the present invention contrasted with a conventional;

FIG. 2 illustrates simulation data associated with the device of FIG. 1;

FIG. 3 illustrates simulated power conversation efficiency vs. current density for a 980 nm laser data according to aspects of the present invention;

FIG. 4 illustrates a diagrammatic representation of a source of voltage defect leveraged according to an aspect of the present invention;

FIG. 5 illustrates a band diagram of a graded AlGaAs structure according to an aspect of the present invention;

FIG. 6 illustrates a diagrammatic representation of an electron quasi Fermi level for an AlGaAs laser according to an aspect of the present invention;

FIG. 7 illustrates a diagrammatic representation of a hole quasi Fermi level for an AlGaAs laser according to an aspect of the present invention;

FIG. 8 illustrates a diagrammatic representation of a hole Fermi level for a broad waveguide Al-free structure according to an aspect of the present invention;

FIG. 9 illustrates a compositional diagram of a low-voltage defect structure according to an aspect of the present invention;

FIGS. 10A and 10B illustrate band diagrams of low-voltage defect lasers according to an aspect of the present invention;

FIG. 11 illustrates the hole Fermi level in the exemplary structure of FIG. 9, without a blocking layer and under 4 kA/cm² current density;

FIG. 12 illustrates a performance characteristics if devices according to aspects of the present invention;

FIG. 13 illustrates a permeable crystalline waveguide SHED device according to an aspect of the present invention;

FIG. 14 illustrates a diagrammatic view of a waveguide structure having a permeable crystal confinement layer according to an aspect of the present invention;

FIG. 15 illustrates an intensity plot of a TE mode according to an aspect of the present invention;

FIG. 16 illustrates a loss calculation versus thickness of a permeable crystal layer according to an aspect of the present invention;

FIG. 17 illustrates calculated modes of a waveguide with a permeable confinement layer with large perforation dimensions illustrating that guided modes penetrate through the permeable layer and anti-guided modes are well confined underneath the permeable layer according to an aspect of the present invention;

FIG. 18 illustrates an intensity plot of a calculated TE mode of a device according to an aspect of the present invention;

FIG. 19 illustrates a ten band calculation for the TE bandgap PCW, highlighting a gap at a/λ;

FIG. 20 illustrates formation of a permeable crystal layer with selective area growth and planar buried regrowth according to an aspect of the present invention; and

FIG. 21 illustrates a schematic illustration of growth condition adjustments for steps d, e and f of the method of FIG. 20.

### DETAILED DESCRIPTION OF THE INVENTION

It is to be understood that the figures and descriptions of the present invention have been simplified to illustrate elements that are relevant for a clear understanding of the present invention, while eliminating, for purposes of clarity, many other elements found in a typical diode apparatus, as well as diode source systems and methods related to the same. Those of ordinary skill in the art will recognize that other elements are desirable and/or required in order to implement the present invention. However, because such elements are well known in the art, and because they do not facilitate a better understanding of the present invention, a discussion of such elements is not provided herein.

According to an aspect of the present invention, an approach of reducing low voltage defect may be used to provide a high efficiency diode laser system. The low voltage defect laser system may include at least one p-clad layer, at least one n-clad layer, and at least one waveguide having a plurality of quantum wells. The at least one waveguide is sandwiched between the p-clad layer and the n-clad layer, such that the quantum wells are offset towards the p-clad layer. According to an aspect of the present invention, at least one permeable crystal layer may be embedded in the p-clad layer immediately adjacent to the at least one waveguide.

According to an aspect of the present invention, a method of forming a high efficiency laser may be provided. The method includes growing an AlGaAs layer atop a GaAs layer, etching of the AlGaAs into a submicron structure, oxidizing the AlGaAs, SAG undoped growing of an SAG undoped GaAs atop the GaAs layer, and regrowing, with p⁺⁺ doped GaAs, of a planar-buried p++ GaAs layer.

According to an aspect of the present invention, pump lasers may be integrated into a high efficiency solid-state laser. For example, an advancement of approximately 60% to 80% PCE provides for an increase in emitted power of about 2.7 times for a solid-state laser limited by heat rejection. Similarly, an about 90% PCE enables an about 6.0 times increase in emitted power.

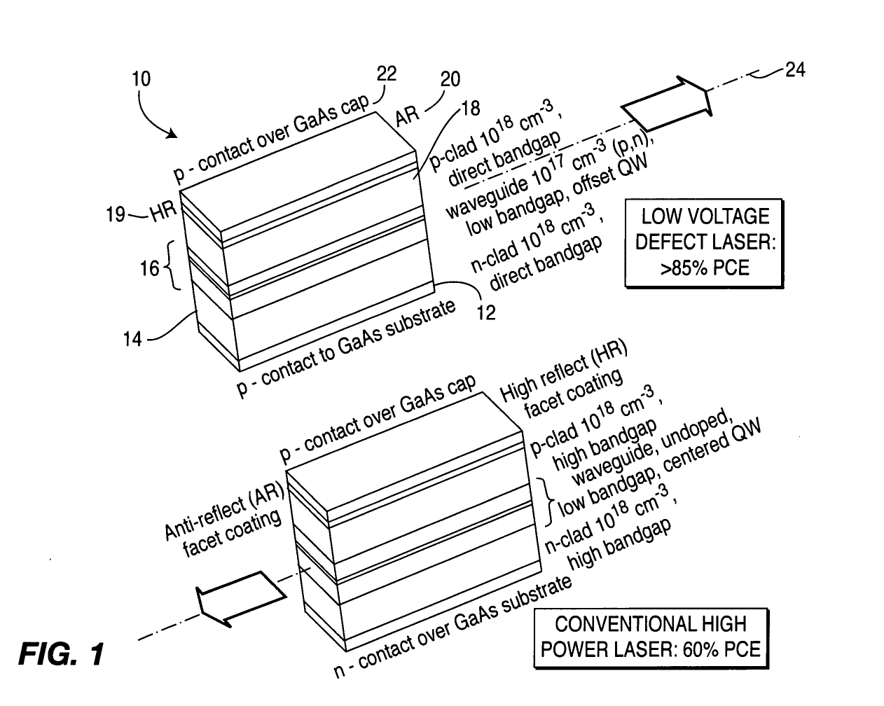

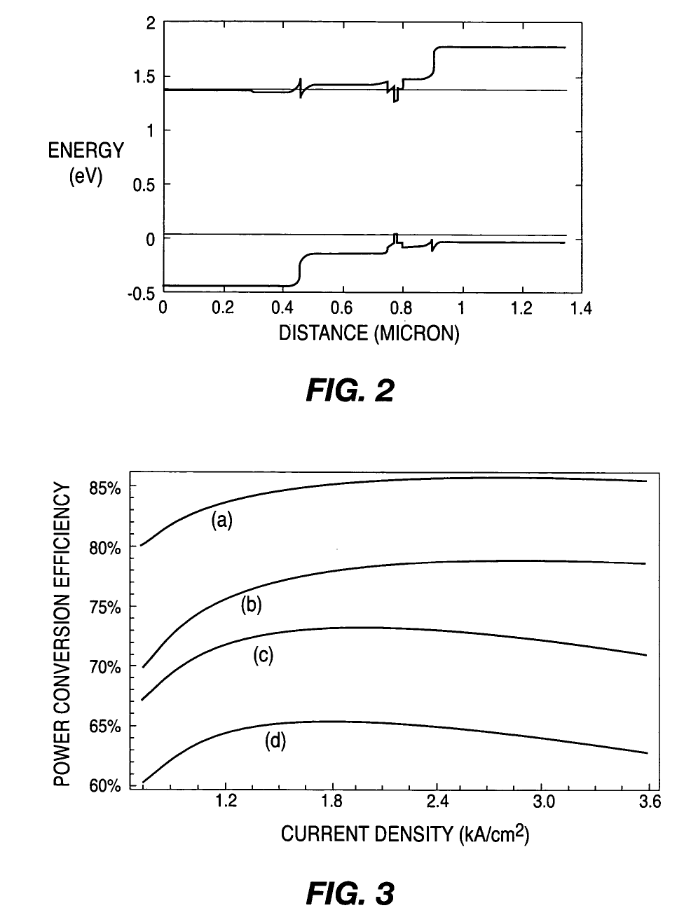

In an exemplary embodiment, in a Low Voltage Defect Super High Efficiency Diode Source (LVD SHED), and in order to improve PCE, a low voltage defect (LVD) approach, as is illustrated in FIGS. 1 and 2, may employ an epitaxial design to reach 85% intrinsic PCE at, for example, 980 nm. LVD SHED 10 may include a GaAs substrate 12 incorporating an n-contact, an n-cladding layer 14, waveguide structure 16, p-cladding 18, high- and anti-reflective coatings 19, 20, and a p-contact over a GaAs cap 22. Waveguide structure 16 may include offset quantum wells 24. SHED 10 may also include an n-clad 14 and GaAs substrate 12.

More particularly, LVD SHED 10 may include a waveguide structure 16 doped to facilitate unipolar diffusion, quantum well offset 24 toward p-cladding 18 to facilitate diffusion of lower-mobility holes, and direct band gap materials. P-cladding 18 and n-cladding 14 may have an approximately 10¹⁸ cm⁻³ direct bandgap, while structure 16 exhibits a 10¹⁷ cm⁻³ (p,n) low bandgap.

According to an aspect of the present invention, LVD SHED 10 may achieve a high PCE and improved control over wavelength. These quantities may be related because nonuniform pumping along a laser bar results when wavelength of emission varies, such as owing to thermal variations.

According to an aspect of the present invention, epistructures may be optimized to maximize efficiency. For example, an LVD SHED according to an aspect of the present invention may generate 80 Watts from a 1 cm bar, such as a bar including 320 stripe lasers each of 250 mW (with 34 mm pitch), 80 lasers of 1 Watt, or any methodology apparent to those skilled in the art. An optimum current density in such an exemplary embodiment may be about 2.5 kA/cm², which corresponds, for a 0.01×0.1 cm² stripe, to 2.5 amperes, or about 3 Watts if 90% PCE is obtained.

FIG. 3 illustrates simulated PCE performance of several structures. Curve (a) thereof illustrates performance of an exemplary LVD design, wherein a 0.4 μm wide waveguide having a cladding/waveguide composition of Al_{0.3}Ga_{0.7}AS/Al_{0.1}Ga_{0.9}As is used. The cladding may be doped 10¹⁸ cm⁻³ with asymmetrical positioning of the quantum wells as has been set forth. This may provide a high intrinsic power conversion efficiency. Curve (b) illustrates performance of a 1 μm wide waveguide having analogous doping and composition, but with symmetrically positioned quantum wells. Curve (c) illustrates performance of a system analogous to that of (b), but where the cladding composition is Al_{0.7}Ga_{0.3}As. Finally, curve (d) illustrates performance of a system analogous to that of curve (b), but with lower doping in the cladding (10⁻¹⁷ cm⁻³) in layers with thickness ˜0.3 microns that are adjacent to the waveguide.

PCE may not be, as was previously thought, inherently limited to about 60%. PCE may be at least partially independent of extrinsic series resistance, and may not improve sufficiently even if contact and ohmic resistances are eliminated. Thus, limitations on PCE typically may not arise from extrinsic series resistance, contrary to conventional theory. For example, the concept that specific resistance is typically in the range of 5×10⁻⁵ Ω-cm² is not believed entirely correct. This reported series resistance is the dynamic resistance measured under forward bias, and takes into account both ohmic and non-ohmic parts. The non-ohmic parts may be, in fact, a manifestation of voltage defect. Therefore, up to 85% PCE may be obtainable if propagation loss could be further reduced, that is, if the actual ohmic contribution to resistance was well below the measured value.

Instead, PCE may be, in actuality, limited by heterobarriers and diffusion gradients. According to an aspect of the present invention, a reduction in PCE may be provided such that the individual contributions to voltage defect can be measured and addressed, and more specifically the present invention addresses whether a particular differential resistance is ohmic or an intrinsic feature of a heterojunction.

More particularly, lasers are conventionally limited to 65% PCE if voltage defect, V_{defect}, exceeds 10×kT/e=250 mV. Voltage defect is given by the deviation of quasi-Fermi levels from constant, as discussed further hereinbelow. The voltage defect is that excess portion of bias voltage, V_{bias}, not explained by ohmic series resistance, V_{defect}=V_{bias}−(V_{ideal}+I_{bias}×R_{ohmic}). In an ideal case of 100% PCE, laser bias voltage is photon energy divided by electron charge, V_{ideal}=hole. FIG. 2 illustrates that relatively subtle changes to laser material structure can dramatically affect PCE, and such changes employed in the design of an LVD laser may include, for example: (1) doping of the waveguide to levels of ¹⁰^{17 cm}⁻³, permitting unipolar diffusion while optical losses remain <1 cm⁻¹; (2) offsetting the quantum well towards the p-clad, facilitating hole diffusion transport to the quantum well; and (3) using direct bandgap materials to provide a high diffusion constant.

In an LVD laser, holes are typically required to transit from direct bandgap materials in the cladding layers to the low bandgap materials of the waveguide. This heterobarrier interface, as discussed hereinthroughout, introduces a discontinuity in the quasi-Fermi level which directly contributes to the voltage defect. Although heterobarrier defects can be mitigated by doping to facilitate intraband tunneling, sufficiently high doping to facilitate intraband tunneling within a laser may cause excessive optical propagation loss. The trade-off between propagation loss and threshold current effects is thus historically a limitation to PCE. Longer devices have lower threshold current, but higher power loss, due to optical propagation effects, thereby creating the need for a relatively highly doped waveguide region to improve the diffusion properties of carriers.

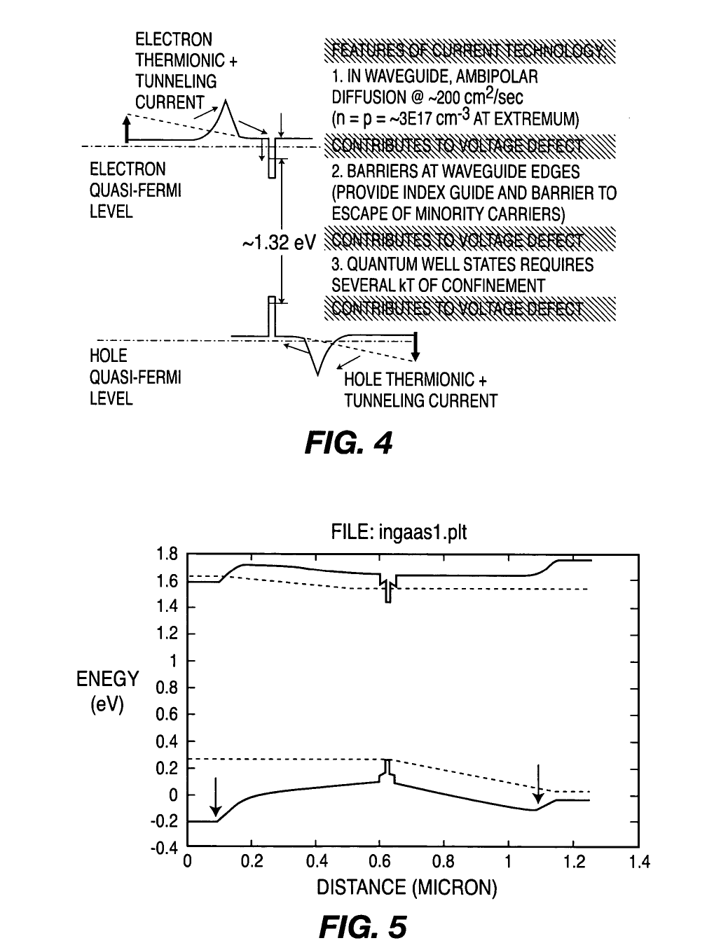

In a laser heterostructure there exist certain processes that propel charge carriers towards radiative recombination and that give rise to a loss of energy. For a non-graded structure, such as the traditional aluminum free design, and as is graphically illustrated in FIG. 4, the discontinuity in bandgap at the interface between waveguide and clad layers may result in the dissipation of carrier potential. Diffusion of carriers towards the active region requires a gradient of carrier density that is associated with a gradient in the quasi-Fermi level. Capture of the carriers by the quantum well represents a small additional dissipation of energy. Specifically, these processes together form the voltage defect. Since there are six such processes, i.e. three processes of each polarity, and between one and two kT of energy may drive these processes, in a traditional laser approximately 10 kT of energy is dissipated by an electron-hole pair in the process of recombining, thereby negatively affecting PCE.

Voltage defect may be minimized, thereby further improving PCE, by the choice of materials in a LVD system. For example, an AlGaAs/GaAs system may present superior LVD characteristics over, for example, an Al-free InGaP/InGaAsP/GaAs system. Such minimization of voltage defect in accordance with the choice of materials is generated, in part, by the voltage defect decrease provided as mobility increases and as the valence band offset decreases. Electron and hole mobility in direct band gap AlGaAs compositions are higher than in InGaP, and the valence band offset is also higher in an Al-free system than in an AlGaAs/GaAs structure. Thus, mobility and distribution of band-offset between conduction and valence bands may give an advantage in PCE to aluminum-containing materials. Further, as to the exemplary embodiments discussed herein, the ability to embed photonic crystal or grating resonant structures may require regrowth on aluminum-containing materials.

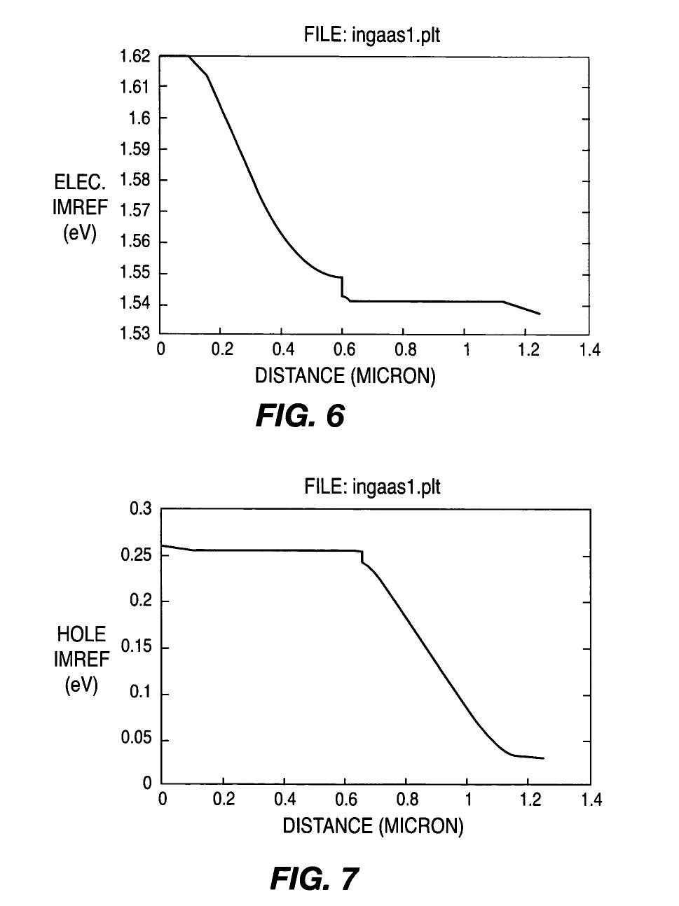

Referring now also to FIG. 5, there is shown a band diagram illustrating a broad waveguide AlGaAs/InGaAs graded structure, with a waveguide width of 1 um and compositional grading from Al_{0.3}Ga_{0.7}As in the cladding to A_{0.1}Ga_{0.9}As near the quantum well region, at a current density 4 kA/cm². The arrows of FIG. 5 mark the boundaries of the waveguide region. The N-type cladding is on the left and the P-type cladding is on the right, as illustrated. The electron and hole quasi Fermi levels are not constant in the waveguide region, as illustrated. The drop of the Fermi levels is not negligible, and thus produces voltage defect. FIGS. 6 and 7 show the Fermi levels of electrons and holes in the waveguide region on an enlarged scale.

The drop of Fermi levels is more pronounced for holes than for electrons, due to lower hole mobility. Together, the Fermi level drops illustrated constitute a voltage defect that reaches DV˜0.3 eV. With this voltage defect, the power efficiency of this exemplary embodiment is limited by the value Vo/(Vo+DV), where Vo˜1.25 eV (the photon energy corresponding to a 980 nm wavelength). With the inclusion of optical losses, the voltage defects of this embodiment preclude the approach of 80% PCE.

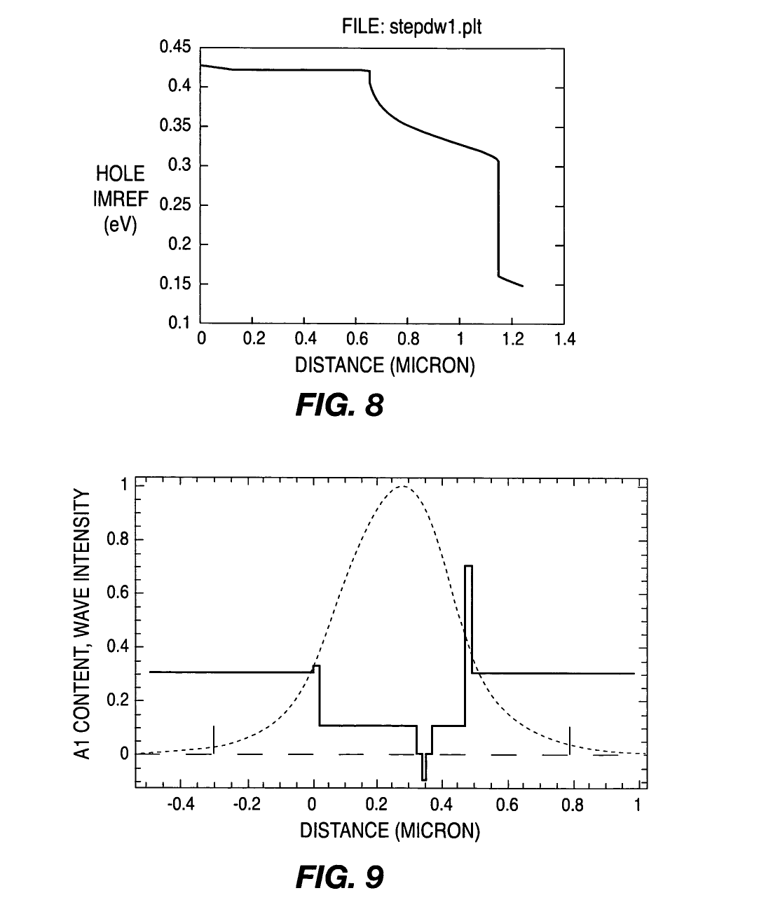

FIG. 8 is a graphical representation, similar to that of FIGS. 5, 6, and 7, for an Al-free structure, which is analogous to a broad waveguide laser. This structure may include, for example, a broad step index InGaAsP waveguide with two embedded quantum wells, wherein the waveguide width is a variable 1−1.2 mm, and having an InGaP cladding. The broad waveguide facilitates low optical losses on the level ˜1 cm⁻¹. This structure also develops a voltage defect, in part from hole transport, as illustrated in FIG. 8.

A Fermi level drop in such a configuration occurs both in the p-side of the waveguide and on the waveguide/cladding boundary. In an InGaP/InGaAsP/GaAs system, the valence band offset comprises ˜60% of the total band gap, rather than the ˜40% in AlGaAs/GaAs in the direct band gap region. This distribution of band offsets is unfavorable for obtaining low voltage defect in Al-free materials, in part because hole flow is more difficult through heteroboundaries due to the lower hole mobility.

Voltage defect may be minimized in a structure having medium sized waveguides with asymmetrical positioning of the quantum wells. An asymmetrical position of the quantum wells generally is not used in a broad waveguide structure, due to the existence of an asymmetrical mode with a node in the middle of such a waveguide structure. However, if the quantum well is positioned in the waveguide center, this asymmetrical mode has very low overlap with gain region and is not excited so long as the quantum well is not displaced from the waveguide center. The compositional diagram of this structure, and the waveguide mode of the structure, is presented in FIG. 9. A low voltage defect, on the order of 20-30 mV, is developed in this structure, up to current densities of 5 kA/cm².

In the LVD laser of FIG. 9, there is an overlap of the laser mode with the cladding. However, only ˜1% of laser mode intensity penetrates into the cladding deeper than ˜0.3 μm. Thus, this region of laser mode intensity penetration may be lightly doped. However, to facilitate hole transport through the heterobarrier, a very thin layer, such as a layer having a thickness ˜20 nm, may be heavily doped. Absorption losses in this heavily-doped layer may be very small due to the thinness of the layer. This thin layer may be grown from the broad band gap material, as illustrated in FIG. 9, to thereby block possible electron leakage.

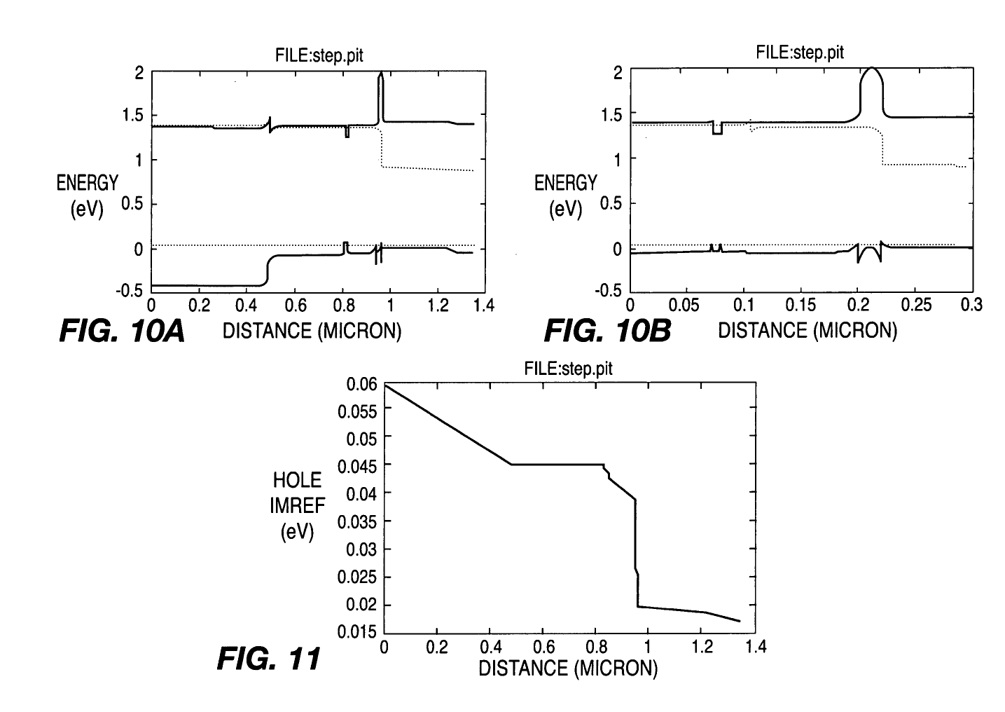

Additionally, in order to address the overlap of the laser mode with the cladding, the mechanisms of optical and electrical confinement may be separated by the use of a permeable crystal confinement layer, as discussed hereinbelow. In such an embodiment, the p-type cladding semiconductor element of the permeable cladding may be, for example, substantially pure GaAs. GaAs provides both lower absorption and higher conductivity than AlGaAs and InGaAsP. A heavily doped current blocking layer from broad band gap material may prevent electrons from flowing into the p-cladding. This heavily-doped layer may be very thin, thereby causing only insignificant absorption losses. The band diagram of such an LVD laser with a thin blocking layer of Al_{0.7}Ga_{0.3}As, and a permeable layer for optical mode confinement under current injection, is illustrated in FIGS. 10a and 10b.

In FIG. 10a, a permeable layer from the p-side of the p-n junction is placed on the right side of the blocking layer. The Fermi levels are near constant in the waveguide region, and the hole Fermi level drops very little in the barrier. However, the electron Fermi level drops sharply in the blocking layer, thereby illustrating very low penetration of electrons through the blocking barrier. In FIG. 10b, the band diagram around the barrier layer is shown on an enlarged scale. The different barriers encountered by the electrons and the holes result in a large difference between electron and hole tunnel currents, in spite of the larger effective mass of holes.

FIG. 11 illustrates the hole Fermi level in the exemplary structure of FIG. 9, without a blocking layer and under 4 kA/cm² current density. An insignificant Fermi level drop of ˜25 mV occurs between the p-cladding and quantum well.

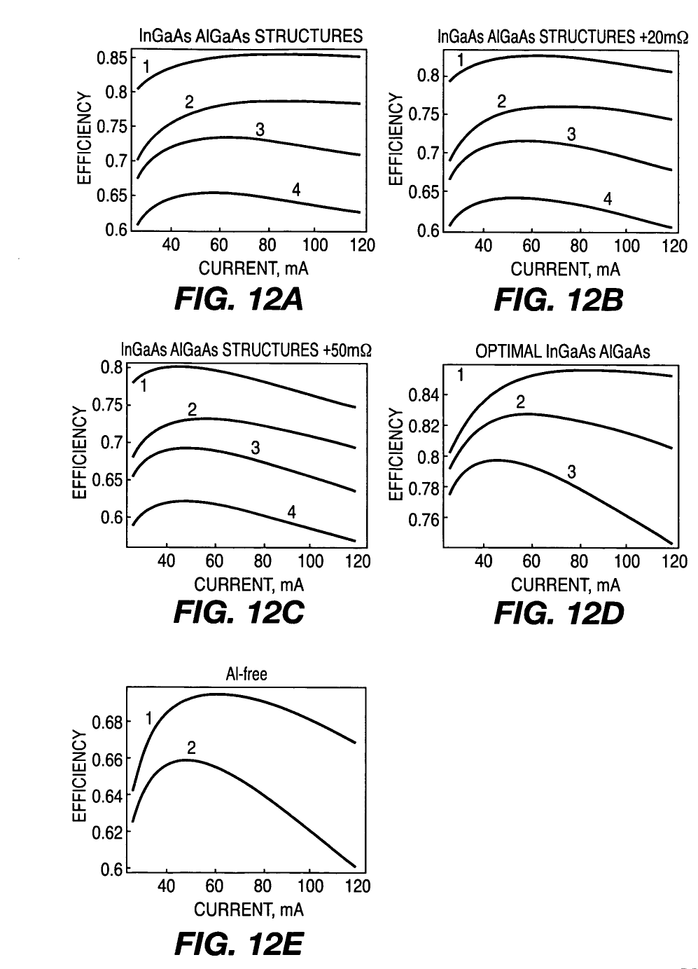

Influence of the voltage defect on power conversion efficiency is presented in FIGS. 12(a)-12(e) for a variety of structures discussed hereinthroughout. For example, FIG. 12a illustrates power conversion efficiency as a function of laser current for four laser designs, namely (1) the design of FIG. 9; (2) similar composition and doping to the design of FIG. 9, but with broad waveguide of 1 um width and symmetrical position of quantum well; (3) similar to embodiment (2), but with a cladding composition of Al_{0.7}Ga_{0.3}As; and (4) similar to embodiment (3), but with doping in the cladding changed from 10¹⁸cm⁻³ to 10¹⁷cm⁻³ in the layers of thickness 0.3 um adjacent to the waveguide. FIG. 12(b) illustrates the results in an exemplary embodiment wherein a series resistance of 20 mΩ is added, wherein the resistance is calculated per stripe 1 mm length and 100 um width. FIG. 12(c) illustrates results in an exemplary embodiment wherein a series resistance of 50 mOhms is added. FIG. 12(d) illustrates results for an embodiment of the present invention such as that illustrated in FIG. 9, without additional resistance (1), with additional resistance 20 mΩ, (2), and with additional resistance 50 mΩ, (3). FIG. 12(e) illustrates results for a broad waveguide Al-free structure, without additional resistance and with additional resistance 50 mΩ.

The illustrations of FIG. 12(a)-(e) are based on an idealized broad stripe laser model with laser length 1 mm, high reflective coating from one side, and low reflective coating with reflection coefficient ˜1% on the output facet, with internal losses 1 cm⁻¹. Stripe width is assumed to be 3 μm, but the results are scalable with stripe width.

As discussed hereinabove with respect to FIGS. 10a and 10b, a limitation on achieving high power conversion efficiencies are the potential voltage defects, and in particular the interface between confinement layer and upper p-cladding. More particularly, waveguiding has been traditionally achieved by using materials of different compositions. Doing so results in band discontinuities that contribute to voltage defect. The use of permeable crystalline waveguide (PCW) may eliminate this interface.

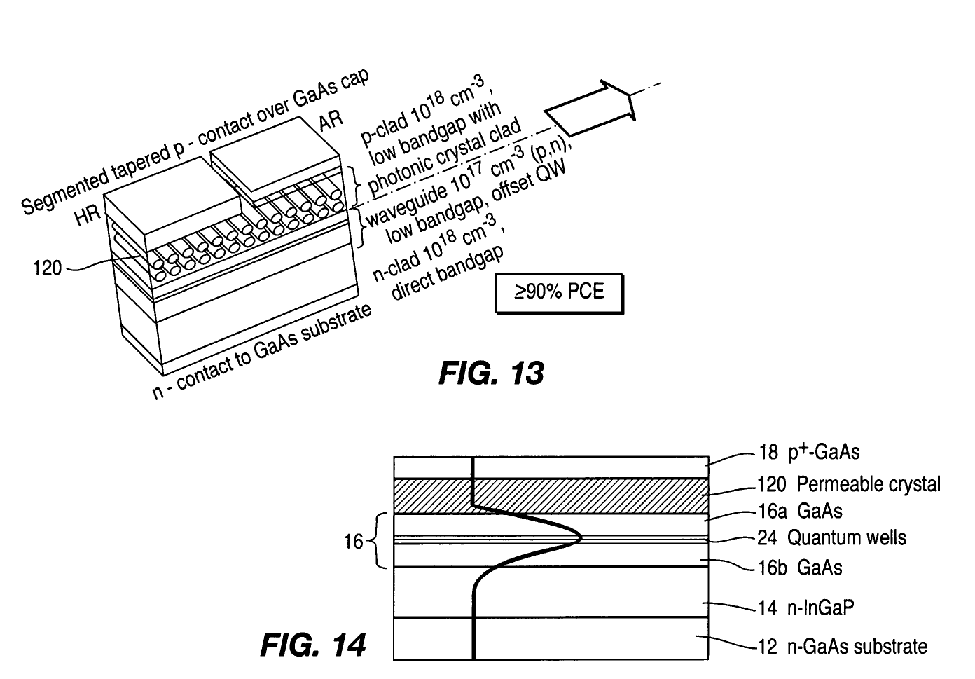

A Permeable Crystalline Waveguide (PCW) device, as illustrated in the embodiment of FIG. 13, includes a structure of crystalline waveguides that allow continuous transport of carriers through low bandgap materials. The PCW structure is similar to the structure of FIG. 1, but additionally includes a photonic crystal layer 120 embedded in the p-clad. The PCW structure, at least in part, eliminates the p-clad heterobarrier, thus contributing to a lowering of voltage defect. By eliminating this drawback, the illustrated embodiment may exceed 90% intrinsic PCE, in part by allowing holes to flow in the interstices of the photonic crystal 120 embedded in the p-clad 18.

In an exemplary embodiment, vertical waveguiding may be accomplished by introducing a lateral structure into the device shown in FIG. 14. As illustrated, a laser may be divided as a p-side, closest to the p+ GaAs layer, and an n-side, closest to the n-layer. The exemplary embodiment may include, for example, the permeable crystal layer 120, embedded between the p+ layer 18 and a GaAs layer 16a. The opposing GaAs layer 16b may sandwich the quantum wells 24, thereby forming the waveguide 16. The opposing GaAs layer 16b may be adjacent on its opposing side to the n-layer 14. The n-side of the waveguide, as illustrated, may contain, for example, an AlGaAs layer, or an InGaAsP layer, to provide guiding of light. At the p-side, a permeable photonic crystal provides guiding of the light. The permeable crystal of the present invention may be based on GaAs structured by, for example, etching or selective area growth techniques.

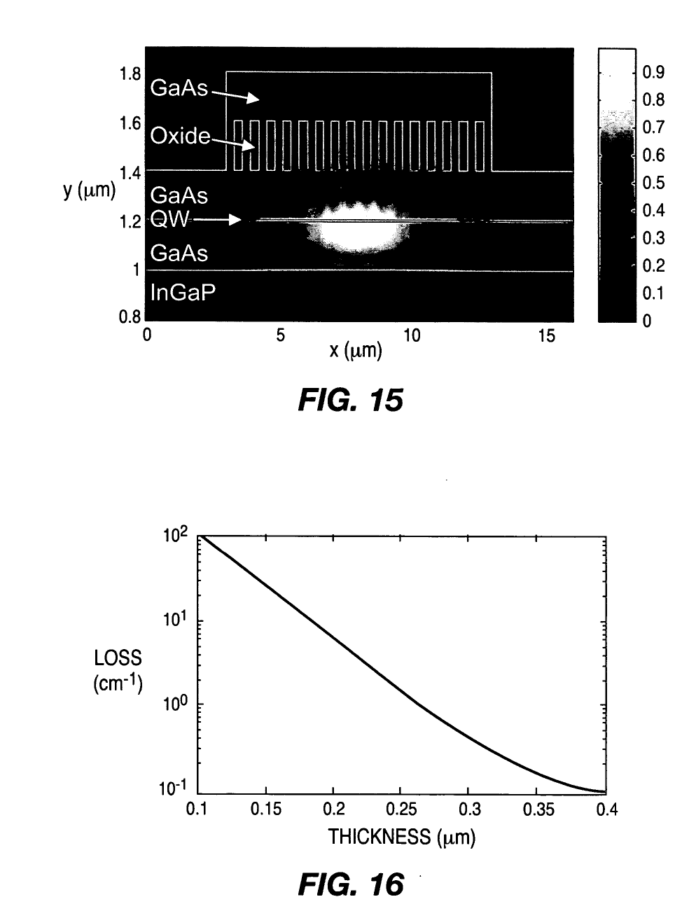

FIG. 15 is an intensity profile plot illustrating the calculated fundamental mode in a 10 μm wide waveguide, in accordance with the embodiment of FIG. 14. As illustrated, the permeable crystal layer provides excellent confinement of the mode on the p-side. As illustrated, bars of lower index (oxide) run in parallel to the light propagation direction. The bars as illustrated are, in this non-limiting exemplary embodiment, 0.3 μm wide and 0.3 μm thick. With such exemplary sub-wavelength dimensions, light is not able to penetrate through gaps between the Al oxidized bars. Optical losses in such structures, other than scattering losses, principally result from leakage of the mode through the permeable layer and absorption losses. FIG. 16 is a graphical illustration showing the optical loss dependence on the thickness of the permeable layer. In this exemplary one-dimensional calculation, the permeable layer has been replaced with a layer having an averaged refractive index. As illustrated in FIG. 16, losses of 0.3 cm⁻¹ are achieved with an exemplary layer thickness of 0.3 μm.

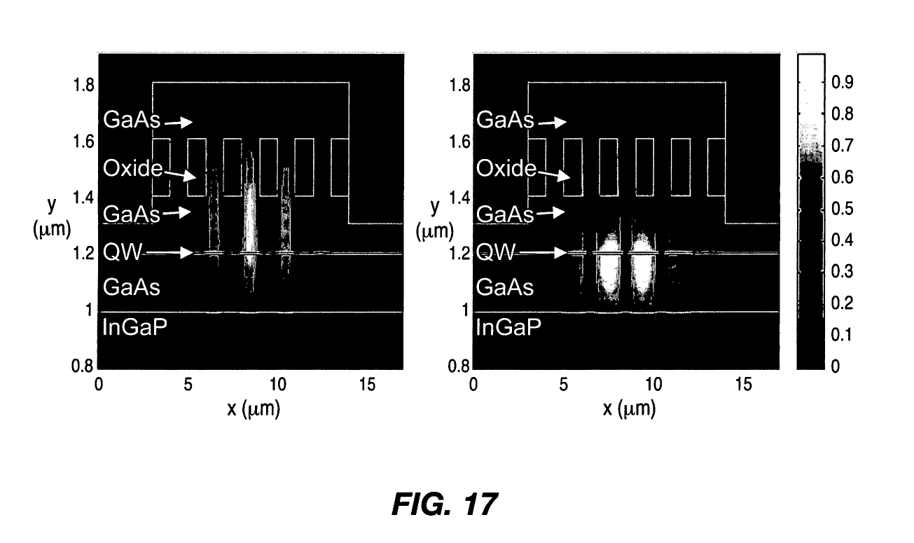

Increasing the dimensions of the permeable layer illustrated in FIG. 14 may enable a wave to pass partially through the layer, as shown in FIG. 17a. In FIG. 17a, the width of the bars and the gaps therebetween have been increased to 1 μm. This results in excessive losses due to large overlap with the highly p-doped upper GaAs material, and due to losses at the metal interface. Nonetheless, this structure also supports anti-guided modes, such as that shown in FIG. 17b. The loss of such anti-guided mode may be substantially lower due to the improved confinement.

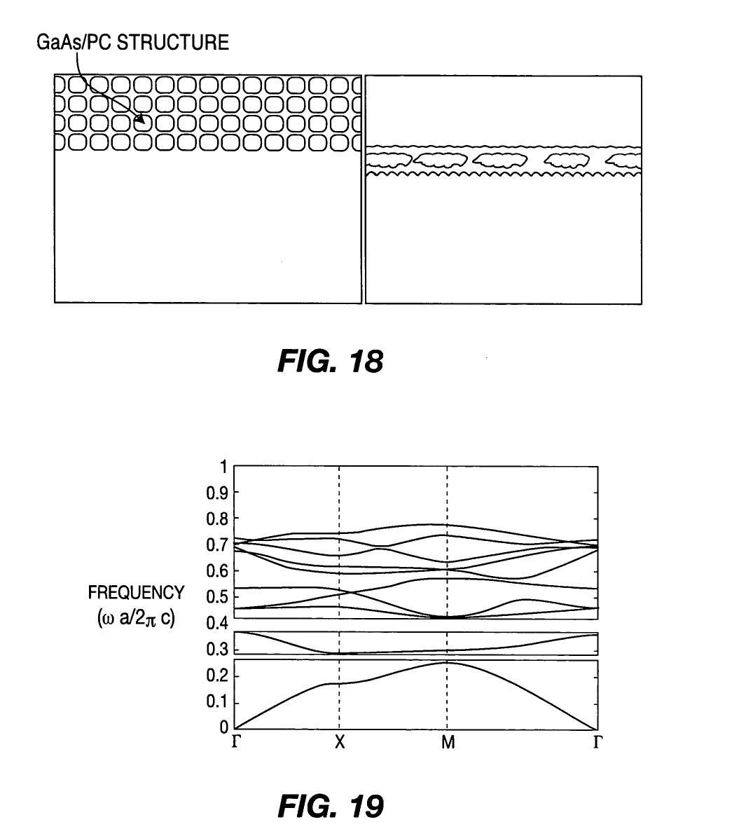

FIG. 18 is a simulation of the PCW of FIG. 14 using a two dimensional FDTD method. In the embodiment of FIG. 18, the PCW includes a photonic crystal clad square lattice having, for example, r=0.16 μm and a=0.39 μm, and layers including 2.8 μm of InGaP (n=3.35) lower clad, 0.4 μm of GaAs (n=3.525) active region, and 2 μm of PC/GaAs (n=1/n=3.525) top clad. FIG. 19 shows the confining of light by a photonic crystal p-clad to the waveguide, while also permitting an aluminum free pathway for hole conduction through the GaAs interstices. The photonic crystal bandgap diagram of FIG. 19 illustrates the choice of crystalline parameters to provide a barrier for light penetration in the PCW structure.

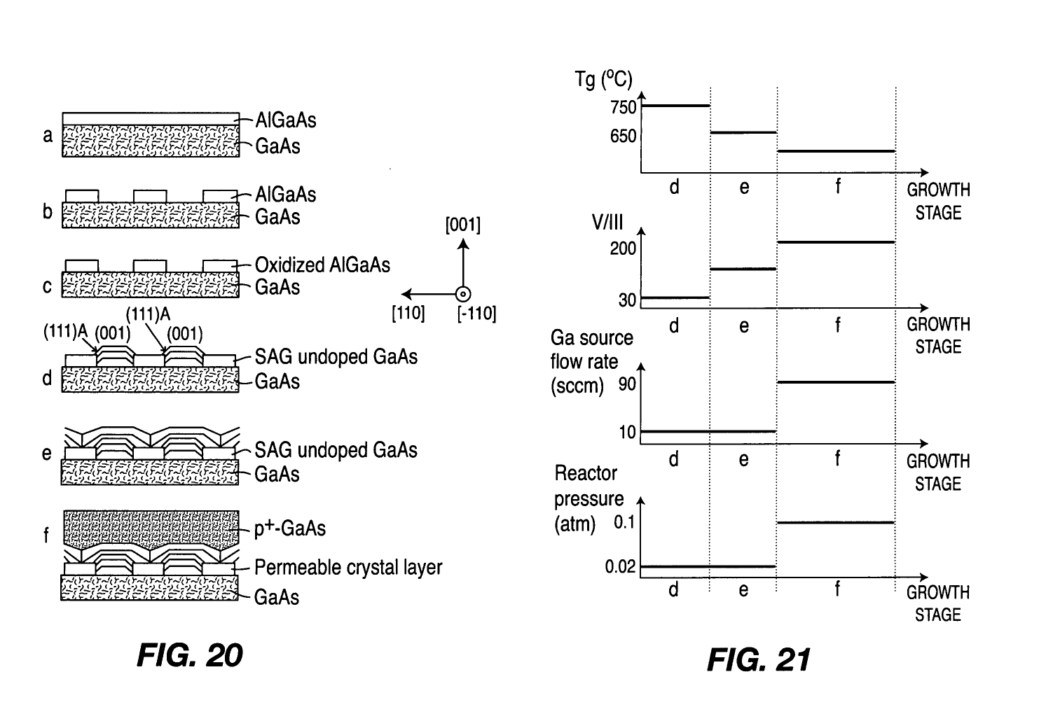

FIG. 20 is a schematic diagram illustrating the fabrication of a permeable crystal layer, such as a PCW layer, with selective area growth (SAG) undoped GaAs layer and a planar buried p⁺⁺ GaAs regrowth layer, in accordance with an aspect of the present invention. The illustration of FIG. 20 is discussed herein with regard to a plurality of steps, although the labeling of those steps in FIG. 20 is not intended to impart a particular order to the performance of those steps. An AlₓGa₁₋ₓAs layer (x>0.8) 206 may be grown on top of the GaAs structure 208, as illustrated in step a. Etching of the AlₓGa₁₋ₓAs layer and subsequent oxidization may result in a submicron oxide stripe pattern, as illustrated in steps b and c. Because growth is inhibited on the areas of oxidized material, this oxide pattern can also act as mask during the subsequent SAG undoped GaAs layer.

Stripes, such as those illustrated in FIG. 20, may be selected along the [-110] direction so that side facets, which define the SAG GaAs stripes, are (111)A facets. At this SAG step, a relatively high growth temperature, such as T_{g} on the order of about 700° C. to 750° C., a low growth rate, and a low V/III ratio may provide high-crystal-quality GaAs between the Al oxide stripes. Prior to SAG growth, the surfaces of opening GaAs windows may be cleaned at the growth temperature, while the Al oxide patterns are maintained. Because the oxides on the GaAs surface may consist of Ga₂O₃ and As₂O₃, the desorption temperature is typically about 400° C. and 550° C. (depending the reactor pressure), respectively. The AlₓGa₁₋ₓAs oxide layer produced in accordance with FIG. 20 may typically consist of Al₂O₃ and As₂O₃. As₂O₃ will be easily desorbed in the same way as GaAs, however, Al₂O₃ is very stable to high temperature.

At the SAG growth condition, as step d shows, the growth rate of side facets (111)A is much smaller than that of top (001) surface. After the spaces between the oxide pattern have been filled with high-crystal-quality undoped GaAs material, the growth conditions may be changed to relatively low T_{g}, such as about 650° C., and high V/III ratio, and the top surface growth rate, i.e. the same Ga source flow rate, may be maintained. At this growth condition, illustrated in step e, the growth rate of the side facets (111)A is increased, and that of the top (001) surface is approximately maintained. This is due to the difference of the surface atomic configuration between each facet, namely that the (111)A surface of GaAs is terminated by Ga atoms, but the (001) surface is terminated by As atoms.

As the V/III ratio is increased, i.e. as the AsH3 partial pressure is increased, the probability of As adhering to Ga increases. Therefore, the growth rate for the (111)A facet will increase. The growth rate for the (001) surface is not strongly dependent on growth temperature, but the growth rate is strongly dependent on the growth temperature for (111)A and (110) facets. The growth rate for (111)A facets increases as the growth temperature decreases, in part because the As on (111)A surface is desorbed at high T_{g}, whereas when the T_{g} is lower the (111)A surface is likely to have excess As thereby leading to the growth rate increasing on (111)A.

The increase in the (111)A facet growth rate causes epitaxial lateral overgrowth (ELO). Thereby, when GaAs grows laterally, the side face changes from a (111)A to a (110) facet. The ELO layer is continuously in touch with the Al oxide film. Furthermore, lateral growth results in the fusing of each GaAs strip over the Al oxide strips, as illustrated in step e. Generally, in the case of this fusion, collision in this manner among same growth modes will generate a very low number of dislocations, or defects.

Subsequently, growth conditions may be changed to those of the planar buried p⁺⁺ GaAs regrowth condition, such as after the spaces between the GaAs stripes have been connected by ELO. At this regrowth condition, T_{g} may be further reduced, such as to <650° C., and the growth rate may be increased, i.e. the Ga source flow rate may be increased, and the V/III ratio may be further increased, along with the reactor pressure. Under this growth condition, more carbon atoms, which may act as p type dopant in GaAs materials, may be incorporated in the p⁺⁺ GaAs layer. The valley between the stripes may become more shallow, and may finally vanish as the p⁺⁺ GaAs layer grows thicker, as illustrated in step f, due, in part, to low surface energy shape. The Al oxide pattern may be buried with high quality undoped GaAs between, and flat surface p⁺⁺ GaAs on top, such as by using different steps within the same run by adjustment of growth conditions. FIG. 21 is a schematic illustration of growth condition adjustment at different growth stages for steps e,d and f of FIG. 20.

Those of ordinary skill in the art will recognize that many modifications and variations of the present invention may be implemented. The foregoing description and the following claims are intended to cover all such modifications and variations falling within the scope of the following claims, and the equivalents thereof.

1. A laser system, comprising:
at least one p-clad layer;
at least one n-clad layer;
at least one waveguide comprising at least a plurality of quantum wells, wherein said at least one waveguide is sandwiched between said p-clad layer and said n-clad layer, and said plurality of quantum wells is offset toward said p-clad layer with respect to said n-clad layer.

2. The laser system of claim 1, wherein at least said p-clad layer comprises a direct bandgap material.

3. The laser system of claim 1, wherein at least said n-clad layer comprises a direct bandgap material.

4. The laser system of claim 1, wherein said at least one waveguide comprises at least one at least one layer including at least one dopant to facilitate unipolar diffusion.

5. The laser system of claim 4, wherein the at least one dopant comprises a dopant level of about 10^{17 cm}⁻³.

6. The laser system of claim 1, further comprising at least one permeable crystal layer substantially adjacent to said p-clad layer and to said at least one waveguide.

7. The low voltage defect laser system of claim 1, wherein said p-clad comprises an AlGaAs composition.

8. A laser, comprising:
at least one p-clad layer;
at least one n-clad layer;
at least one waveguide comprising at least a plurality of quantum wells, wherein the at least one waveguide is sandwiched between said p-clad layer and said n-clad layer and offset towards said p-clad layer with respect to said n-clad layer; and,
at least one permeable crystal layer embedded in said p-clad layer and substantially adjacent to said at least one waveguide.

9. The laser of claim 8, wherein said at least one permeable crystal layer provides continuous transport of carriers through low bandgap materials.

10. The laser of claim 8, further comprising at least one thin, heavily doped current blocking layer that blocks electrons from flowing into said p-clad layer.

11. The laser of claim 8, wherein said p-clad layer comprises substantially pure GaAs.

12. The laser of claim 8, wherein at least said p-clad layer comprises a direct bandgap material.

13. The laser of claim 8, wherein at least said n-clad layer comprises a direct bandgap material.

14. The laser of claim 8, wherein at least one layer of said at least one waveguide comprises at least one dopant.

15. A method of forming a laser, comprising:
providing a GaAs substrate;
growing an AlGaAs layer atop said GaAs substrate;
etching of the AlGaAs into at least one structure comprising at leats one sub-micron feature;
oxidizing the AlGaAs;
growing an SAG undoped GaAs layer atop the GaAs substrate; and
regrowing, with p⁺⁺ doped GaAs, a planar-buried p++ GaAs.

16. The method of claim 15, wherein said oxidizing and said etching provides a submicron oxide stripe pattern.

17. The method of claim 16, wherein said SAG undoping is at a growth temperature in the range of about 700° C. to 750° C.

18. The method of claim 17, further comprising, prior to said SAG growing, cleaning openings in the AlGaAs layer.

19. The method of claim 16, wherein said regrowing, with p++ GaAs, comprises regrowing after spaces between the submicron stripes have been connected by ELO.

20. The method of claim 15, further comprising delineating a permeable crystal layer upon said regrowing.
